(19) United States
(12) Patent Application Publication
(10) Pub. No.: US 2009/0289738 A1
(43) Pub. Date: Nov. 26, 2009

(54) Filter Characteristics Regulating Method, Filter Characteristics Regulator, Filter, and Communication Apparatus

(75) Inventors: Keiji Yoshida, Fukuoka (JP); Haruichi Kanaya, Fukuoka (JP)

Correspondence Address: STAAS & HALSEY LLP, SUITE 700, 1201 NEW YORK AVENUE, N.W., WASHINGTON, DC, 20005, US

(73) Assignees: Kyushi University National University Corporation, Fukuoka (JP); Fukuoka Industry Science & Technology Foundation, Fukuoka (JP)

(21) Appl. No.: 11/886,638

(22) PCT Filed: Mar. 3, 2006
(86) PCT No.: PCT/JP2006/304155

§ 371 Date: May 18, 2009

(30) Foreign Application Priority Data
Mar. 18, 2005 (JP) 2005-080674

(51) Int. Cl. H03H 7/12

(52) U.S. Cl. 333/132

(57) ABSTRACT

When an attenuation pole produces, highly-efficient-izing and a miniaturization of a filter are enabled by changing the electric length between a branch point and each filter. The 1st band pass filter 5 that has the characteristics of center frequency f1, and the 2nd band pass filter 7 that has the characteristics of different center frequency f2 from center frequency f1, In co-planer filter 3 provided with transmission line 9 which connects the 1st band pass filter 5 and the 2nd band pass filter 7, and branch point 11 formed in transmission line 9. It is designed so that an attenuation pole may produce in either [at least] the 1st band pass filter 5 or the 2nd band pass filter 7, and the frequency region which the formation position of branch point 11 is adjusted and an attenuation pole produces is adjusted.

### FIELD OF THE INVENTION

This invention relates to a filter characteristic regulation method, a filter characteristic regulator, a filter, and a communication apparatus.

It is related with the method of adjusting the characteristics of the filter which especially an attenuation pole produces etc.

### BACKGROUND OF THE INVENTION

In fields, such as mobile communications or satellite communications, development of the microwave device using the characteristics of low-loss of superconductivity is expected.

For example, since the microwave filter can realize a sharp skirt characteristic by low-loss, many things have been proposed as application to mobile communications (refer to nonpatent literature 1).

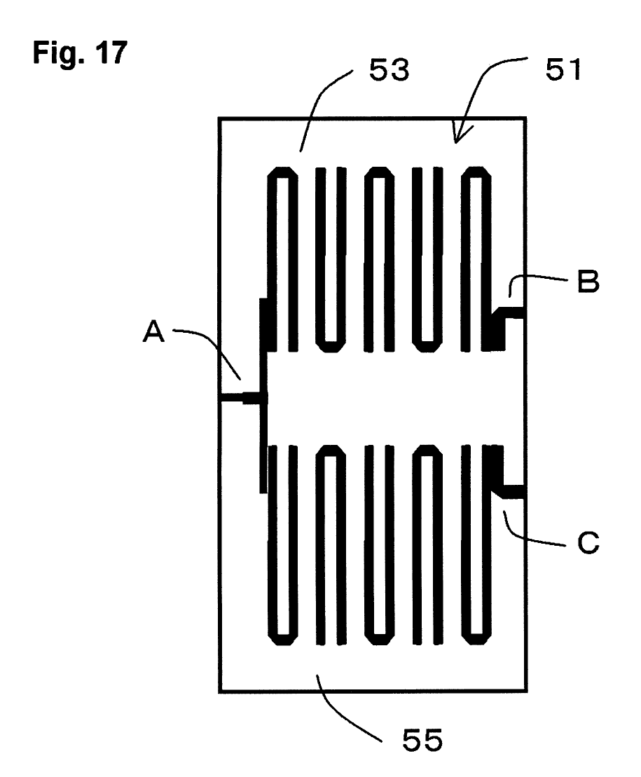

FIG. 17 is a figure showing an example of the conventional filter (superconductivity allotter).

Filter 51 as a superconductivity allotter comprises a hairpin resonance device of microstrip line structure, and is provided with the 1st filter 53 and the 2nd filter 55. For example, the 1st filter 53 and the 2nd filter 55 are the Chebyshev type filters.

For example, by inputting a signal of 2 GHz bands from feeding point A, a signal of a band (1.94 GHz-1.96 GHz) transmits to feeding point C through the 2nd filter 55, and a signal of a band (2.13 GHz-2.15 GHz) transmits to feeding point B through the 1st filter 53.

Here, it is designed so that power distribution may be equally performed to each filter of the 1st filter 53 and the 2nd filter 55.

That is, the electric length of the branch point and each filter which are feeding points A is designed equally.

An inventor has proposed an invention which attains highly-efficient-izing and a miniaturization of a filter which produced an attenuation pole (refer to nonpatent literature 2).

### [Nonpatent Literature 1]

Motonori Takezawa and other 5 work, “Design of a high temperature superconductor allotter, and evaluation” 2003 Institute of Electronics, Information and Communication Engineers electronics society convention C-2-44, p 68

### [Nonpatent Literature 2]

Koji Kawakami, Fuminori Koga, Haruichi Kaneya, Keiji Yoshida work, “Development of high-temperature superconductivity co-planer filter using ¼ wavelength resonator” Institute of Electronics, Information and Communication Engineers technical research report (S C E2004-4), 2004, p 19-24

### DESCRIPTION OF THE INVENTION

### Problem(s) to be Solved by the Invention

An inventor of application paid his attention to a thing was not conceived and “Changing a branch point and electric length of each filter” in the former.

Therefore, the purpose of this invention is to change electric length between a branch point and each filter, when an attenuation pole produces.

This invention offers a filter and a communication apparatus with which a filter characteristic regulation method which enables highly-efficient-izing and a miniaturization of a filter by it, an adjusting device, and highly-efficient-izing and a miniaturization were attained.

### Means for Solving the Problem

An invention concerning Claim 1 is a filter characteristic regulation method which can adjust the filter property of a filter which an attenuation pole produces, and can input a signal into a filter via a branch point.

Or via a filter to a branch point, an output of a signal is possible and a frequency region which adjusts electric length of a transmission line from a branch point to a filter, and an attenuation pole produces is adjusted.

By adjusting a frequency region which an attenuation pole produces, a for example more sharp skirt characteristic can be produced, and a noise can also be eliminated, for example.

Such a filter characteristic regulation method may be regarded as a filter characteristic regulator.

It may regard as a program which makes a computer perform a filter characteristic regulation method, and a recording medium which recorded the program.

An invention concerning Claim 2 is a filter characteristic regulator which can adjust the filter property of a filter which an attenuation pole produces, and can input a signal into said filter via a branch point.

Or via said filter to said branch point, an output of a signal is possible and it has an electric length controller which adjusts electric length of a transmission line from said branch point to said filter.

An invention concerning Claim 3 is a filter characteristic regulator which can adjust the filter property of a filter constituted by plural filter means connected via a branch point.

An attenuation pole produces in at least one of said the plural filter means, and it has an electric length controller which adjusts electric length of a transmission line from said branch point to said each filter means.

Adjustment of a frequency region which electric length is adjusted and an attenuation pole produces by an electric length controller of Claim 2 and Claim 3 is attained.

And by adjusting a frequency region which an attenuation pole produces, a for example more sharp skirt characteristic can be produced, and a noise can also be eliminated, for example.

The 1st band pass filter means in which an invention concerning Claim 4 has the 1st center frequency characteristics,

The 2nd band pass filter means that has the 2nd different center frequency characteristics from the 1st center frequency characteristics,

In a filter provided with an end, a transmission line of the 2nd band pass filter means which connects an end on the other hand, and a branch point formed in a transmission line of the 1st band pass filter means on the other hand

It is designed so that an attenuation pole may produce in either [at least] the 1st band pass filter means or the 2nd band pass filter means, and a frequency region which a formation position of a branch point is adjusted and an attenuation pole produces is adjusted.

By adjusting a frequency region which an attenuation pole produces, a for example more sharp skirt characteristic can be produced, and a noise can also be eliminated, for example.

For example, a signal received from an antenna passes the 1st band pass filter means via a branch point.

A signal which passed the 2nd band pass filter means may be sent to an antenna via a branch point, and may be transmitted outside.

Reception (a signal received from an antenna passes the 1st band pass filter means or 2nd band pass filter means via a branch point.) of a multi-model may be sufficient. Transmission (a signal which passed the 1st band pass filter means or 2nd band pass filter means is sent to an antenna via a branch point, and is transmitted outside.) of a multi-model may be sufficient.

In this case, communication may be performed simultaneously (although it is one way besides simultaneous both directions, it is included in simultaneous transmissive communication here that information which is different by a wave number two or more rounds can transmit or receive etc.).

Thereby, for example in a noncontact IC card or a RFID tag, it also becomes possible to raise safety in distributed communication of a security code.

A frequency region of an attenuation pole which either [at least] said 1st band pass filter means or said 2nd band pass filter means comprises three or more steps of resonance devices, and produces an invention concerning Claim 5 by jump coupling in said resonance device in Claim 4 is also adjusted.

In an invention concerning Claim 6, a filter of Claim 5 is a meander shape and a frequency region of an attenuation pole produced by jump coupling in said resonance device is adjusted by adjustment of a meander radius.

An invention concerning Claim 7 is distinguished and set up in either of Claims 4-6, without a frequency band by said 1st band pass filter means and a frequency band by said 2nd band pass filter means overlapping.

In either of Claims 4-6, a frequency band by said 1st band pass filter means and a frequency band by said 2nd band pass filter overlap, and an invention concerning Claim 8 is set as a wide area.

Three or more band pass filter means from which an invention concerning Claim 9 differs in center frequency characteristics mutually,

In a filter provided with a transmission line which at least two of said three or more band pass filter means connect, and a branch point formed in said transmission line A frequency region of said three or more band pass filter means which a formation position of said branch point is adjusted and said attenuation pole produces while being designed so that an attenuation pole may produce in either at least is adjusted.

An invention concerning Claim 10 is distinguished and set up in Claim 9, without a frequency band by said each band pass filter means overlapping mutually.

In Claim 9, a frequency band by at least two band pass filter means which center frequency characteristics adjoin among said three or more band pass filter means overlaps, and an invention concerning Claim 11 is set as a wide area.

In an invention concerning Claim 12, the filter according to claim 4 to 11 is a co-planer filter.

An invention concerning Claim 13 is a communication apparatus in which input possibility of or said filter to an output is possible in said filter about a signal of frequency which is provided with the filter according to claim 4 to 12, and is mutually different.

An invention concerning Claim 14 is a communication apparatus in which other band pass filter means [some band pass filter means] which can be inputted to an output of a signal of frequency which is provided with the filter according to claim 4 to 12, and is mutually different is possible.

### EFFECT OF THE INVENTION

According to this invention, a frequency region which an attenuation pole produces can be adjusted as mentioned above.

Therefore, the filter property of a filter can be adjusted and it becomes possible to attain highly efficient-ization of a filter.

This highly efficient-ization differs from highly efficient-ization by multi-stage-izing. This becomes possible to attain a miniaturization of a filter, by suppressing a multi stage-ization.

Suppressing multi stage-ization can suppress attenuation of an inputted signal. Therefore, the necessity of amplifying a decreased signal decreases.

Therefore, it will become advantageous also from power consumption.

### BRIEF DESCRIPTION OF THE DRAWINGS

[Drawing 1]

It is a schematic diagram showing the whole communication apparatus concerning an embodiment of the invention.

[Drawing 2]

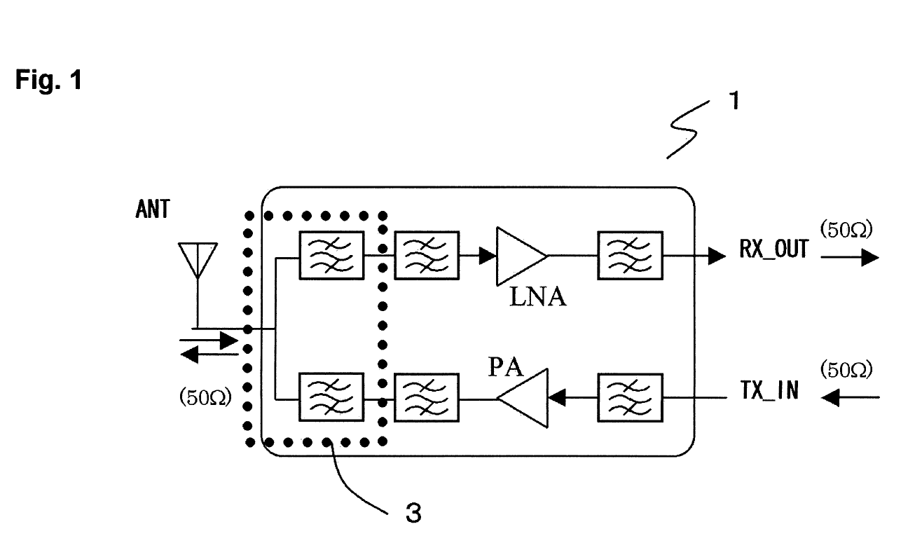

It is a figure showing the filter characteristic regulator which adjusts the attenuation pole produced with co-planer filter 3 of communication apparatus 1 of FIG. 1, and adjusts filter property.

[Drawing 3]

It is a mimetic diagram showing a straight line type co-planer filter.

[Drawing 4]

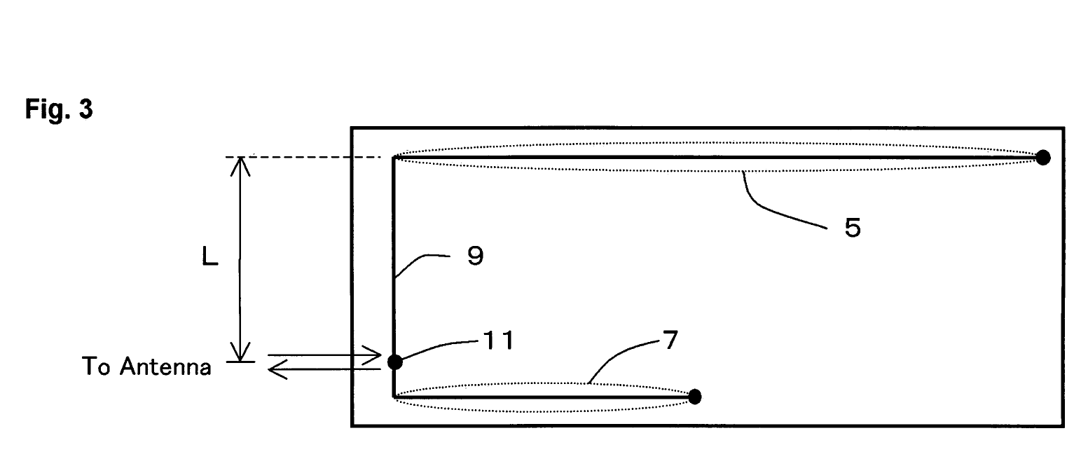

It is a figure showing the simulation result by the regulation of electric length L in FIG. 3.

[Drawing 5]

It is a mimetic diagram showing the co-planer filter of a meander shape.

[Drawing 6]

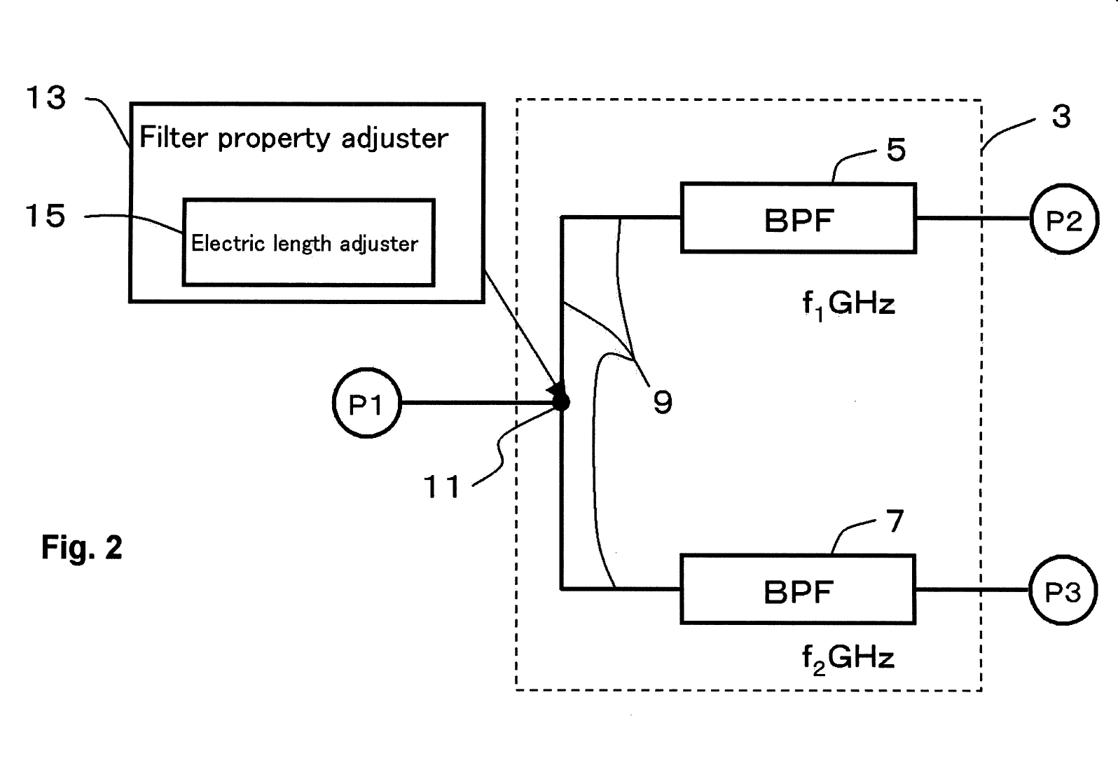

It is a figure showing the result depended on the trial production filter (branching filter) at the time of carrying out the 1st band pass filter 5 (stop frequency is 4.635 GHz) of FIG. 2 reception-side, and making the 2nd band pass filter 7 (stop frequency is 4.9 GHz) of FIG. 2 into a sending end.

[Drawing 7]

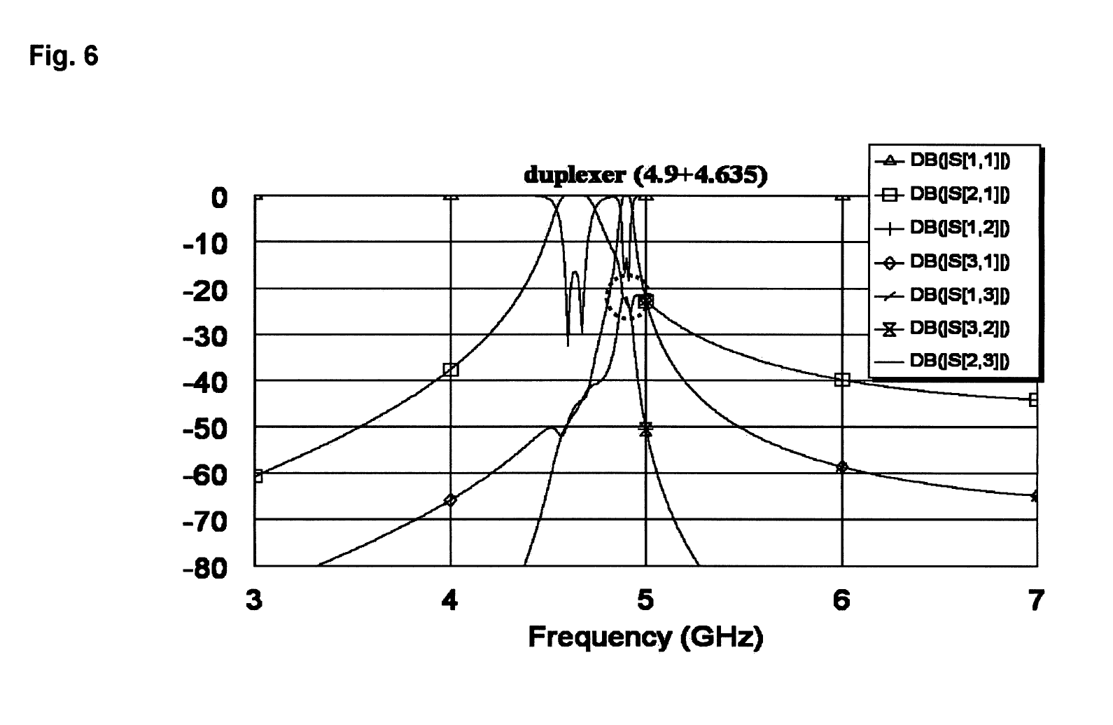

It is a circuit diagram showing the case where the reception side is made into three steps unlike the trial production filter in FIG. 6.

[Drawing 8]

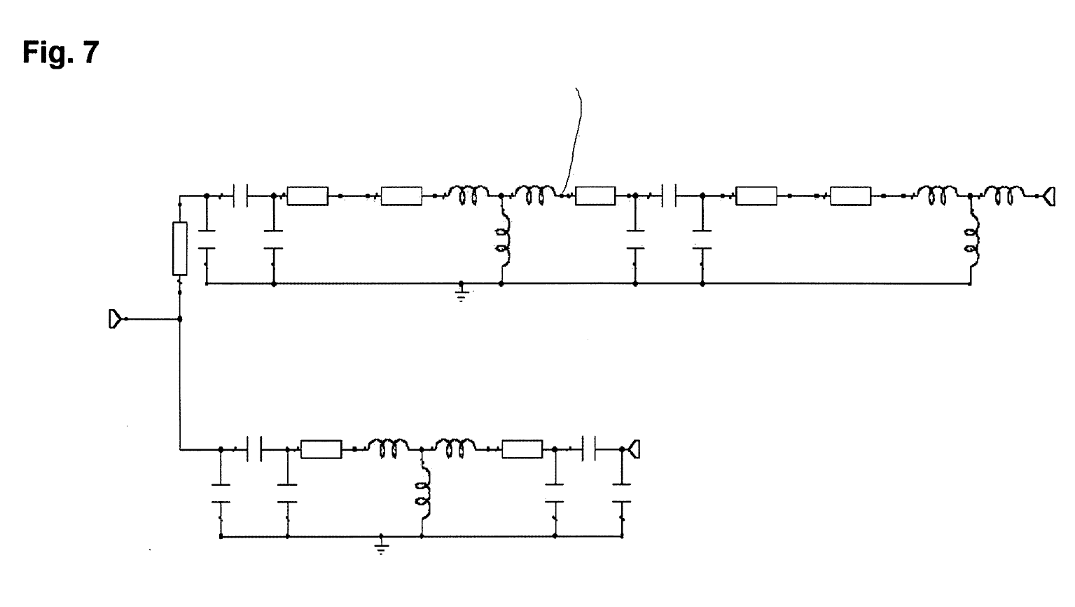

It is a figure showing the result obtained after adjusting the frequency region which changes electric length L in the filter constitution shown in FIG. 7, and an attenuation pole produces.

[Drawing 9]

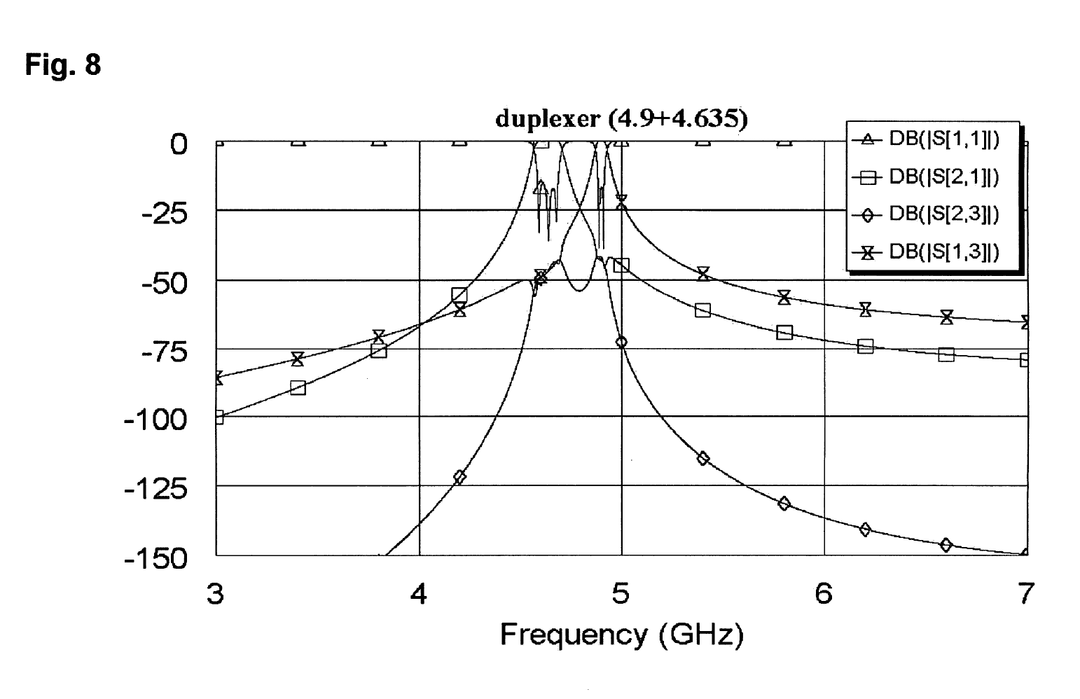

It is a figure showing the isolation in FIG. 8.

[Drawing 10]

It is the circuit diagram in which one-step jump coupling was also included unlike the circuit diagram showing in FIG. 7.

[Drawing 11]

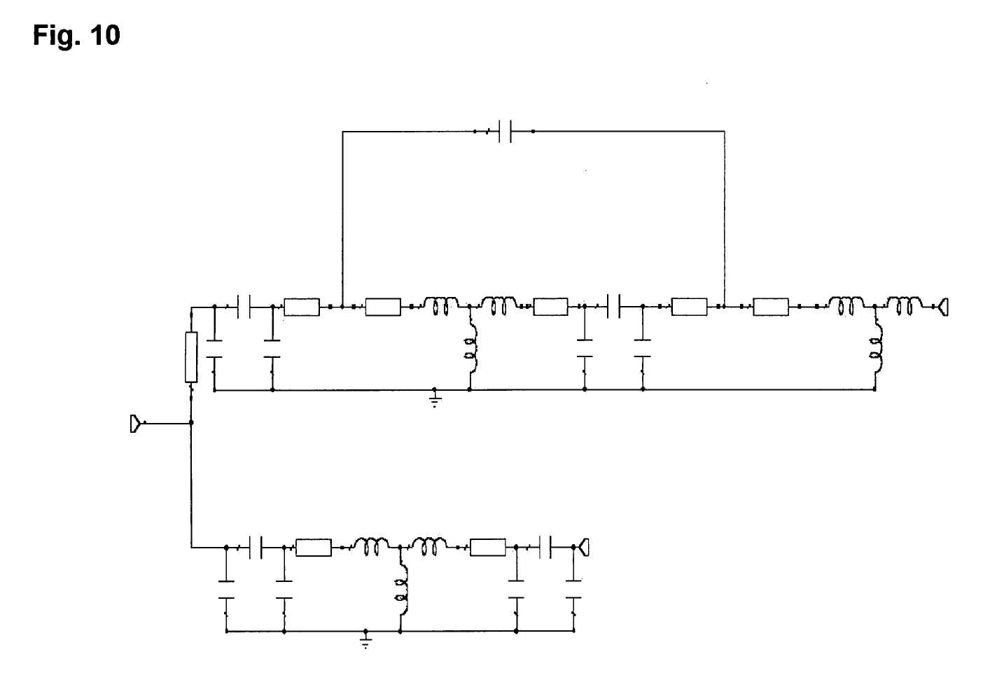

It is a figure showing the result of having made 4.9 GHz which is adjustment and sending end frequency about the frequency region which changes electric length L in the filter constitution shown in FIG. 10, and an attenuation pole produces producing the attenuation pole by one-step jump coupling.

[Drawing 12]

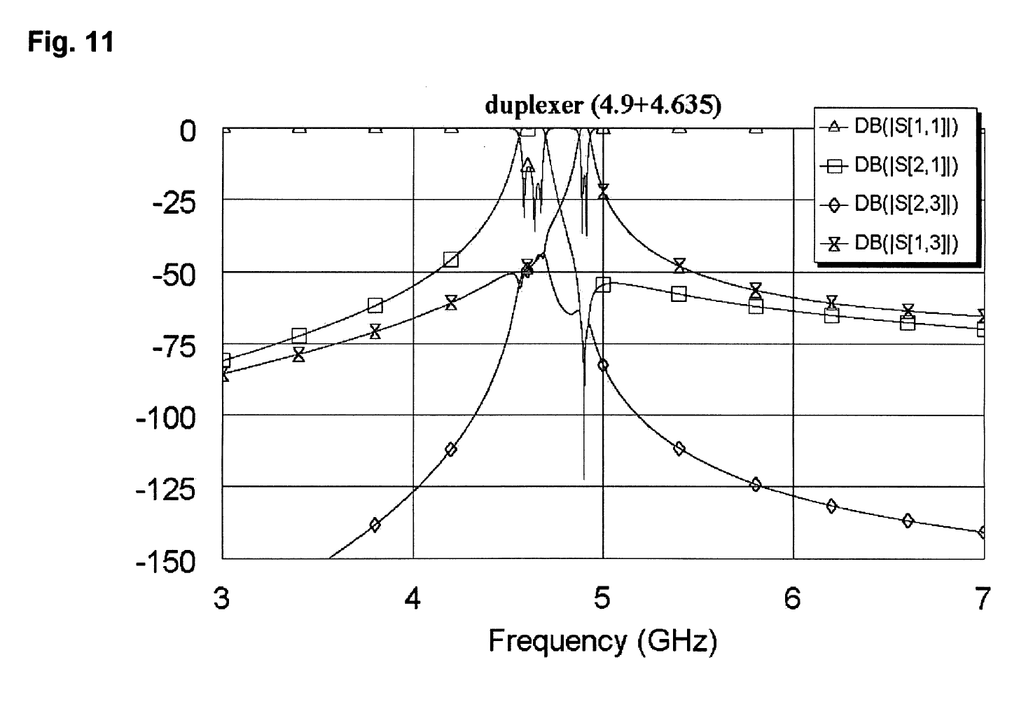

It is a figure showing the isolation in FIG. 11.

[Drawing 13]

It is a circuit diagram showing the state of connecting each of three steps of band pass filter integral-type co-planer waveguide way (CPW) matching circuits to each of three antennas, and making three channels corresponding.

[Drawing 14]

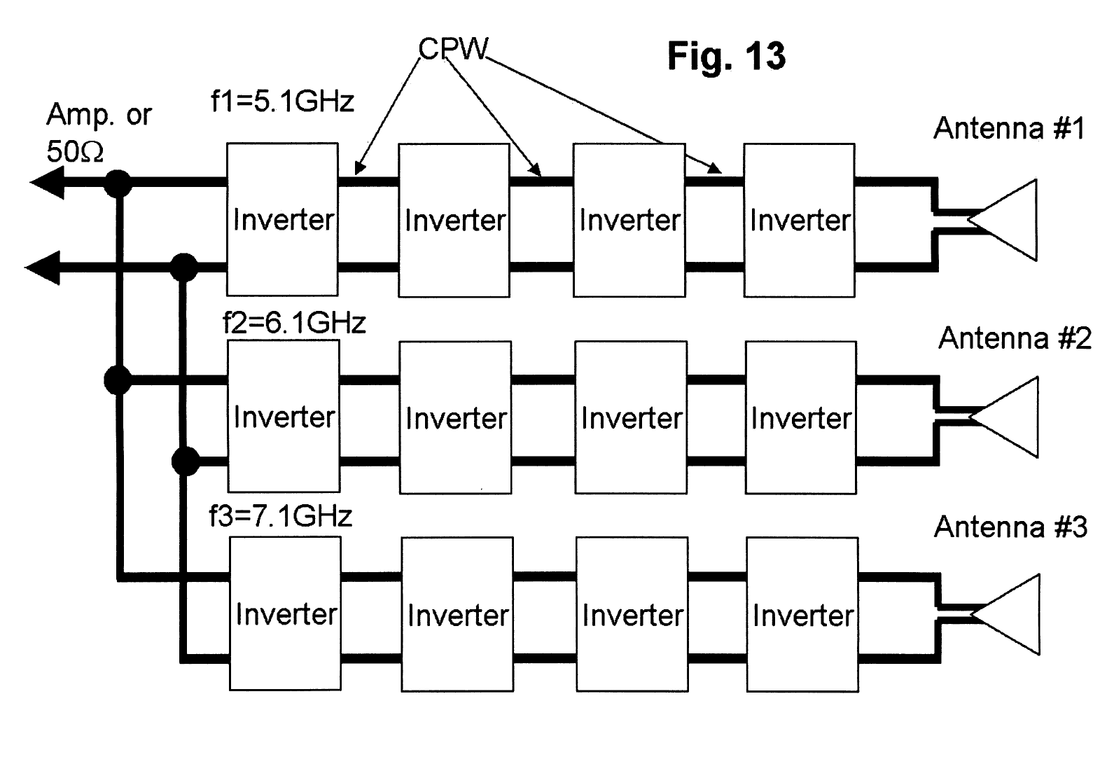

It is a figure showing the result of having performed the simulation based on the circuit diagram of FIG. 13.

[Drawing 15]

It is a circuit diagram showing the state where connected each of three steps of band pass filter integral-type co-planer waveguide way (CPW) matching circuits to each of three antennas, and broadening of 5 GHz bands was attained.

[Drawing 16]

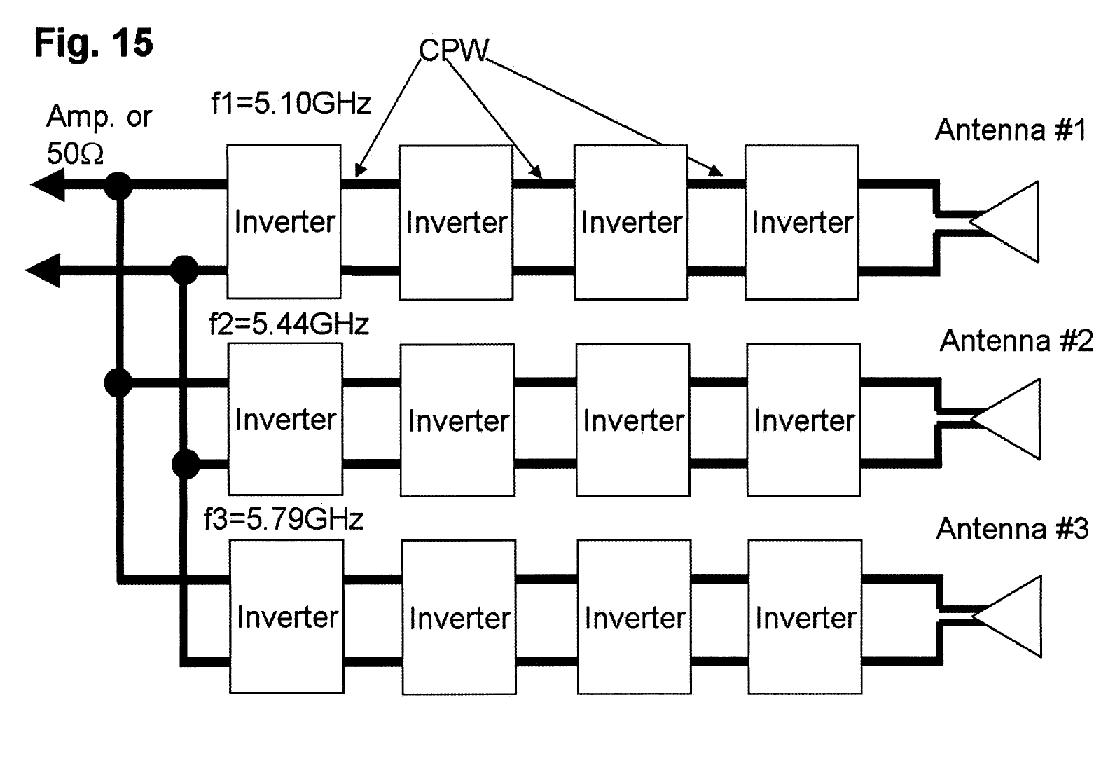

It is a figure showing the result of having performed the simulation based on the circuit diagram of FIG. 15.

[Drawing 17]

It is a figure showing an example of the conventional filter (superconductivity allotter).

### DESCRIPTION OF NOTATIONS

3 Co-planer Filter
5, 7 Band pass filter
9 Transmission Line
11 Branch Point

### BEST MODE OF CARRYING OUT THE INVENTION

FIG. 1 is a schematic diagram showing the whole communication apparatus concerning an embodiment of the invention.

Using antenna ANT, communication apparatus 1 can transmit a signal outside and can receive a signal from the outside.

Communication apparatus 1 is provided with co-planer filter 3.

Co-planer filter 3 works as a passive type switch.

A passive type switch has an advantage of low power compared with the active type switch by a Pin diode etc.

FIG. 2 is a figure showing the filter characteristic regulator which adjusts the attenuation pole produced with co-planer filter 3 of communication apparatus 1 of FIG. 1, and adjusts filter property.

Co-planer filter 3 is provided with the 1st band pass filter 5 that has center frequency f1 GHz filter property, the 2nd band pass filter 7 that has center frequency f2 GHz filter property, transmission line 9 which connects the 1st band pass filter 5 and the 2nd band pass filter 7 and branch point 11 formed on transmission line 9.

By branch point 11, if it sees, for example from the antenna ANT side, it will have branched to the 2-way of the 1st band pass filter 5 and the 2nd band pass filter 7.

Filter characteristic regulator 13 is provided with electric length controller 15, and electric length controller 15 adjusts the formation position on transmission line 9 of branch point 11 by a simulation etc., and adjusts the frequency region which an attenuation pole produces.

Regulation of the electric length from branch point 11 shown below to the 1st band pass filter 5 may be sufficient as regulation of a formation position.

Otherwise, regulation of a formation position may be adjusted by the ratio of the electric length from branch point 11 to the 1st band pass filter 5 to the electric length from branch point 11 to the 2nd band pass filter 7.

FIG. 3 is a mimetic diagram showing a straight line type co-planer filter.

The 1st band pass filter 5 here is a co-planer waveguide way (CPW) band pass filter.

The 1st band pass filter 5 comprises two steps of lambd a/4 resonance devices, 0.1 dB is set as 100 MHz (a band ratio 0.02) for a ripple, and 5 GHz and bandwidth are set as it for stop frequency.

Here, the 2nd band pass filter 7 is a co-planer waveguide way (CPW) band pass filter, it comprises two steps of lambd a/4 resonance devices, and a ripple sets center frequency as 0.1 dB, it is set as 2.45 GHz, and bandwidth is set as 100 MHz (a band ratio 0.04). Such set-up center frequency takes the specification of wireless LAN(Locan Area Network) into consideration.

In such composition, electric length L of transmission line 9 from branch point 11 to the 1st band pass filter 5 is changed and adjusted.

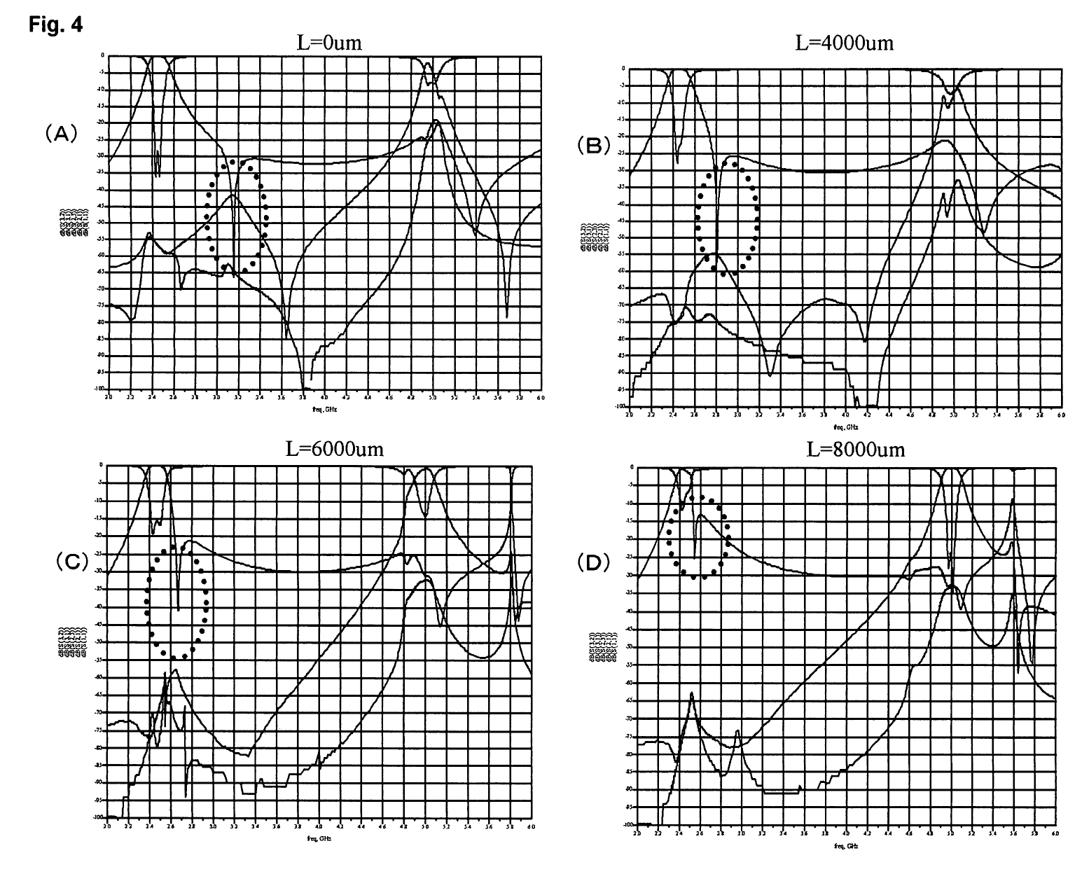

FIG. 4 is a figure showing the simulation result by the regulation of electric length L in FIG. 3.

FIG. 4 (A) shows the case where electric length L is 0 um, FIG. 4 (B) shows the case where electric length L is 4000 um, FIG. 4 (C) shows the case where electric length L is 6000 um, and FIG. 4 (D) shows the case where electric length L is 8000 um.

About the unit in each figure, a vertical axis is a decibel (dB) and a horizontal axis is frequency (GHz).

For example, it is shown in a vertical axis, in dB (S (2, 1)), it corresponds to port P2 in FIG. 2, 1 corresponds to port P1 in FIG. 2, and 2 expresses the amount of passage from port P2 to port P1.

If its attention is paid to dB (S (2, 1)), the attenuation pole shown in the portion surrounded with the dashed line will move to the low frequency region from the high frequency area, so that electric length L becomes long (in turn of FIG. 4 (A), FIG. 4 (B), FIG. 4 (C), and FIG. 4 (D)).

And in FIG. 4 (D), the attenuation pole can be moving even to the center frequency region of the 2nd band pass filter 7 of 2.45 GHz.

Thus, by moving an attenuation pole to a desired frequency region, a skirt characteristic is made with a more sharp thing, for example, and a noise can also be removed, filter property is raised, and highly efficient-ization of a filter can be realized.

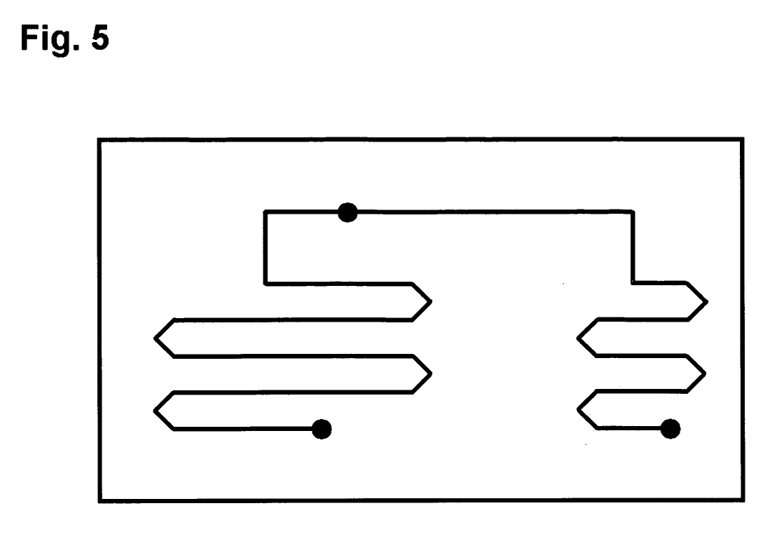

A meander shape as shown in FIG. 5 besides the straight line type which adjusts the frequency region which an attenuation pole produces by regulation of such electric length L, and is shown in FIG. 3 as a filter which can adjust filter property may be used.

Next, including a next-generation cellular phone, effective use of frequency is demanded more than future and now, and it is shown that this invention can be realized also in such a frequency region.

FIG. 6 is carried out the 1st band pass filter 5 of FIG. 2 reception-side, and makes a transmitting side the 2nd band pass filter 7 of FIG. 2.

The 1st band pass filter 5 comprises two steps of lambda/4 resonance devices.

The ripple of the 1st band pass filter 5 is 0.1 dB, center frequency is 4.635 GHz, band width is 100 MHz (a band ratio is 0.02).

The 2nd band pass filter 7 comprises two steps of lambda/4 resonance devices.

The ripple of the 2nd band pass filter 7 is 0.1 dB, center frequency is 4.9 GHz, band width is 30 MHz (a band ratio is 0.06).

FIG. 6 is a figure showing characteristics with the aforementioned trial production filter (branching filter).

The resistance of filter both ends is set to 50 ohms.

In FIG. 6, as a result of adjusting electric length L, as shown in the portion surrounded with the dashed line, the attenuation pole can be moved to a 4.9 GHz frequency region.

From FIG. 7 to FIG. 12 explain the improvement of the trial production filter shown in FIG. 6.

FIG. 7 is a circuit diagram showing the case where a receiving side is made into three steps unlike the trial production filter in FIG. 6.

FIG. 8 is a figure showing the result obtained after adjusting the frequency region which changes electric length L in the filter constitution shown in FIG. 7, and an attenuation pole produces.

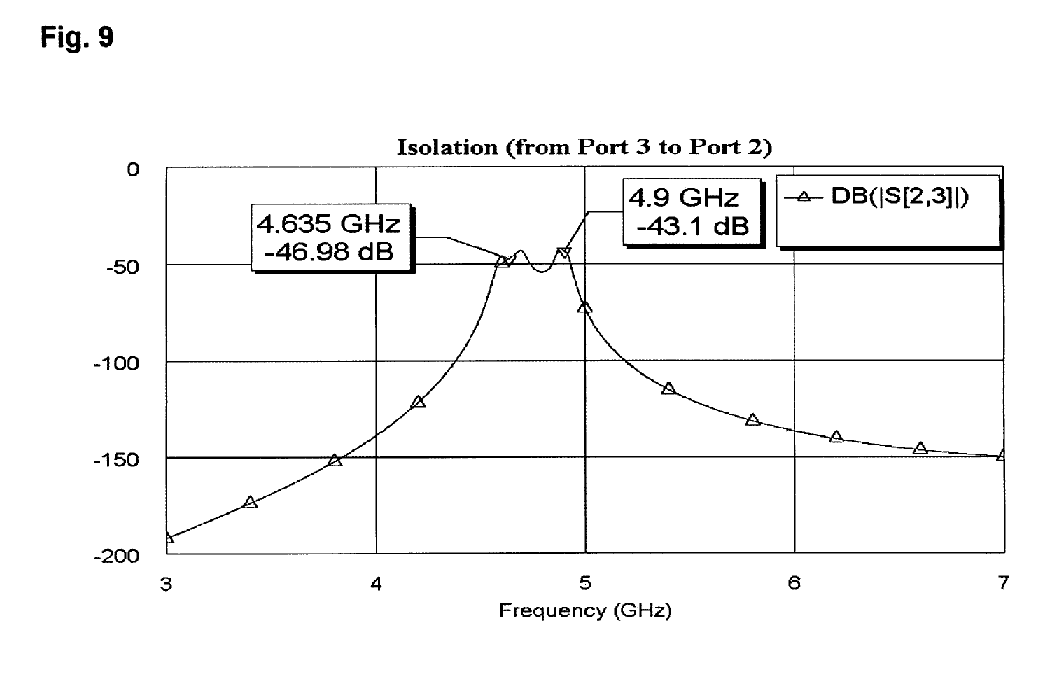

FIG. 9 is a figure showing the isolation in FIG. 8.

As shown in FIG. 9, isolation has become less than −43 dB.

FIG. 10 is a circuit diagram in which one-step jump coupling was also included unlike the circuit diagram showing in FIG. 7.

FIG. 11 is a figure showing the result of an attenuation pole produces by a filter shown in FIG. 10, tuning and one-step jump connection at 4.9 GHz that is a transmitter side frequency, a frequency band that cause an attenuation by changing electric length L.

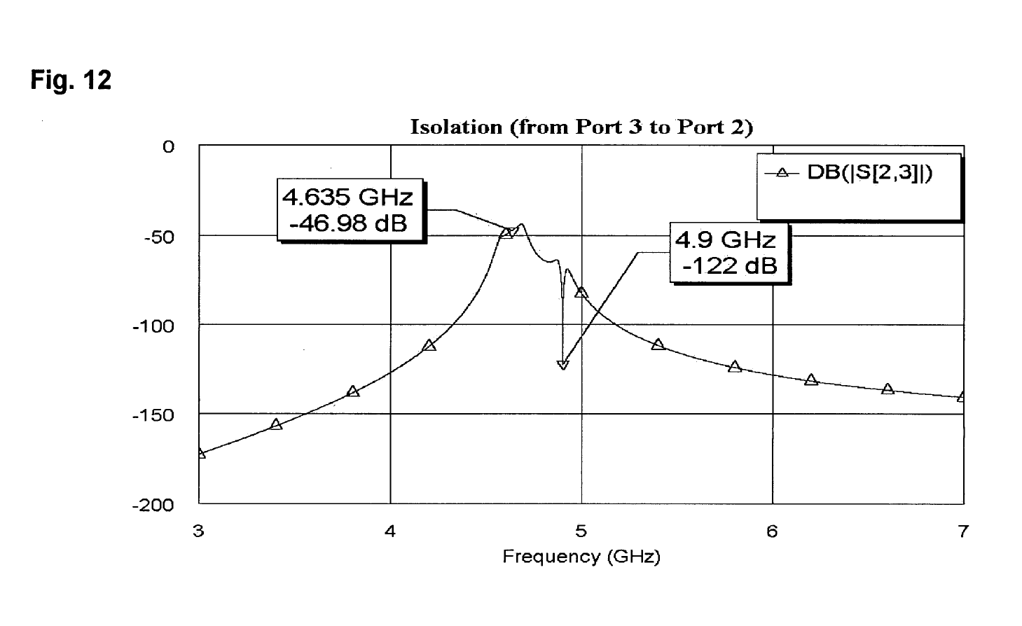

FIG. 12 is a figure showing the isolation in FIG. 11.

As shown in FIG. 12, in 4.9 GHz, it is −122 dB and the high isolation value can be realized.

About producing an attenuation pole by one-step jump coupling, the art indicated by the Institute of Electronics, Information and Communication Engineers technical research report (S C E2004-4), 19-24-2004, etc. was used.

Although 3 stage filters were used and one attenuation pole was produced by one-step jump coupling in the above, the number of section of a filter may be increased, for example, two attenuation poles may be produced by two-step jump.

Control of the attenuation pole produced by jump coupling is possible by changing the meander radius of a meander shape as shown in FIG. 5 using the Institute of Electronics, Information and Communication Engineers technical research report (S C E2004-4) and the art indicated by 19-24-2004.

Six steps of co-planer waveguide way (CPW) band pass filters which provided the attenuation pole symmetrically, for example to the center frequency by jump coupling have obtained the result with characteristics equivalent to eight steps of Chebyshev form band pass filters.

Therefore, by using an attenuation pole appropriately in this way, the number of the resonance devices which constitute a filter can be reduced, and the miniaturization of a filter can be realized.

Finally, the necessity of using an attenuation pole appropriately is increasing.

For example, even if 20 MHz is given as bandwidth to each radio-wave-utilization contractor, big bandwidth like 5 MHz as a guard band is not used in fact.

However, as a result of a skirt characteristic's becoming good by using an attenuation pole appropriately, it is because a guard band can be narrowed.

Since much wireless communications arise not only like a cellular phone but like a noncontact IC card or a RFID tag, a miniaturization is required more.

Thus, effective use of frequency is attained by producing highly efficient-ization of a filter.

Since it becomes possible to also attain a miniaturization, an industrial use meaning of the invention in this application which uses a subtrahend pole appropriately is large.

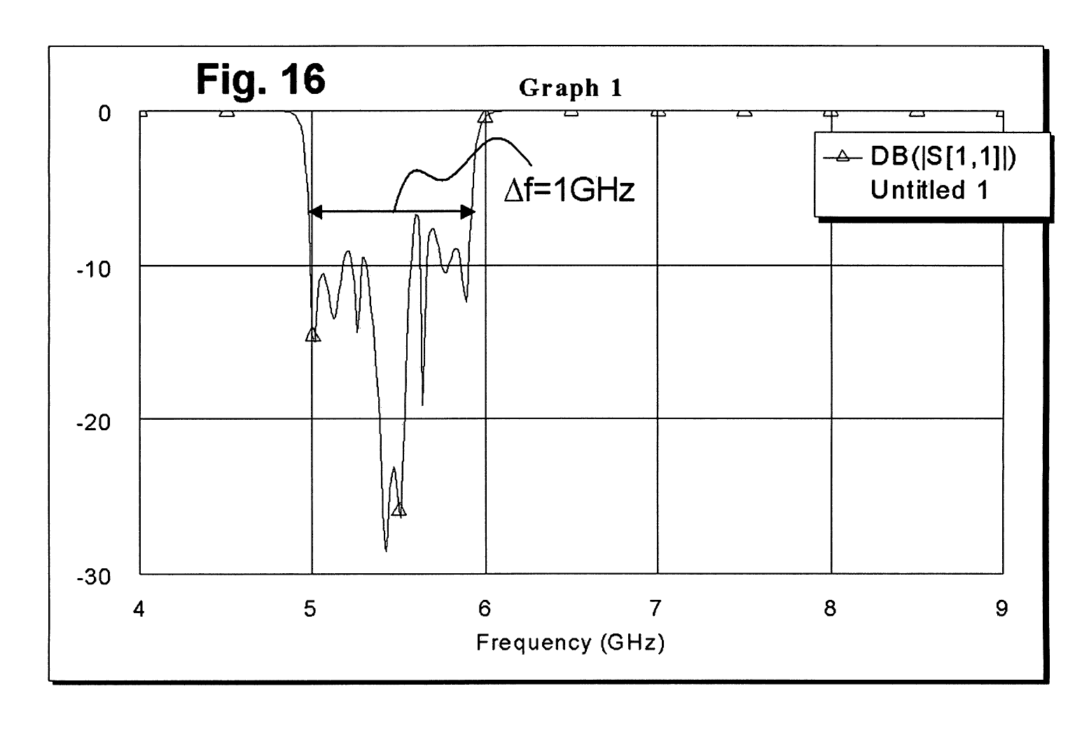

Hereafter, while FIG. 16 shows other embodiments from FIG. 13, the embodiment and the above-mentioned attenuation pole control are described.

FIG. 13 is a circuit diagram showing the state of connecting each of three steps of band pass filter integral-type co-planer waveguide way (CPW) matching circuits to each of three antennas, and making three channels corresponding.

In FIG. 13, center frequency f1 of the band pass filter to antenna #1 and a matching circuit is 5.1 GHz (100 MHz of bands).

Center frequency f2 of the band pass filter to antenna #2 and a matching circuit is 6.1 GHz (100 MHz of bands).

Center frequency f3 of the band pass filter to antenna #3 and a matching circuit is 7.1 GHz (100 MHz of bands).

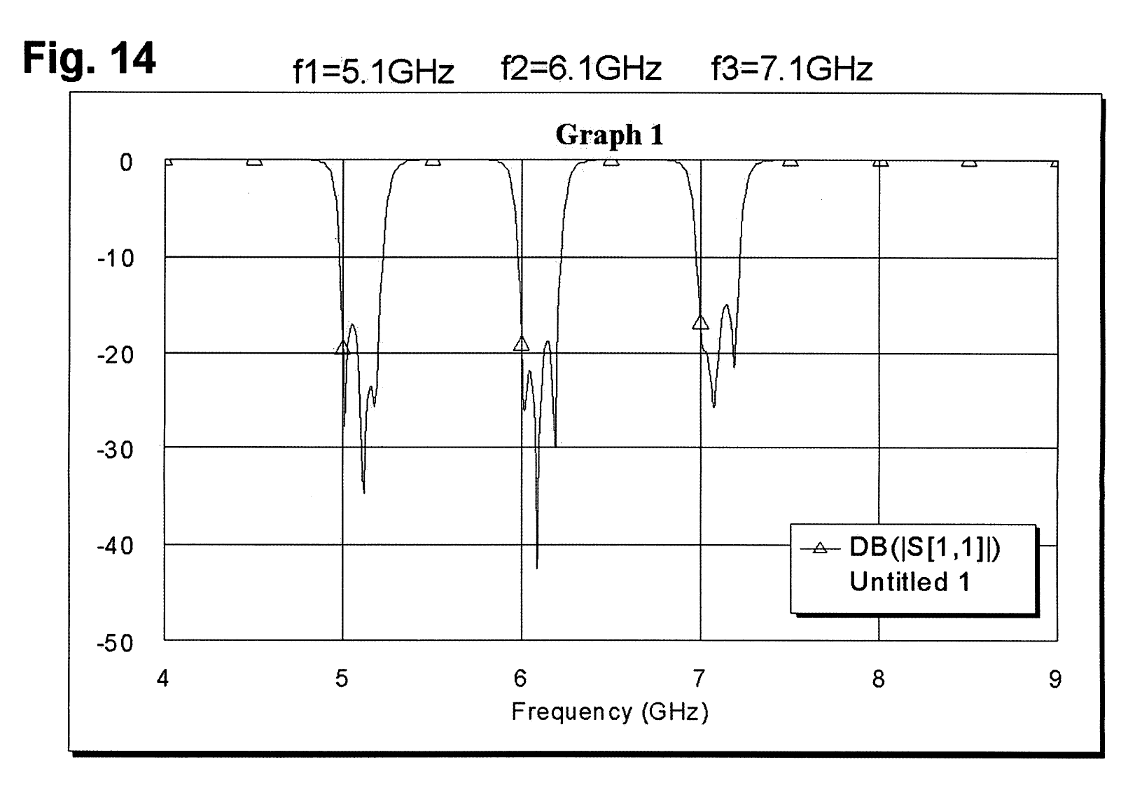

FIG. 14 is a figure showing the result of having performed the simulation based on the circuit diagram of FIG. 13.

From this figure, it becomes clear that plural frequency bands which can be used for transmission and reception are obtained with the filter which the frequency band was distinguished without overlapping mutually and was set up in the communication apparatus obtained from the circuit diagram of FIG. 13.

As the method of use of obtained plural frequency bands, all may be used for transmission, all may be used for receiving, a part may be used for transmission and others may be used for receiving.

FIG. 15 is a circuit diagram showing the state where connected each of three steps of band pass filter integral-type co-planer waveguide way (CPW) matching circuits to each of three antennas, and broadening of 5 GHz bands was attained.

In FIG. 15, center frequency f1 of the band pass filter to antenna #1 and a matching circuit is 5.10 GHz (100 MHz of bands).

Center frequency f2 of the band pass filter to antenna #2 and a matching circuit is 5.44 GHz (100 MHz of bands).

Center frequency f3 of the band pass filter to antenna #3 and a matching circuit is 5.79 GHz (100 MHz of bands).

FIG. 16 is a figure showing the result of having performed the simulation based on the circuit diagram of FIG. 15.

It is clearer than this figure that the frequency band which can be used for transmission and reception of the bandwidth which amounts to 1 GHz with the filter which the frequency band overlapped and was set as the wide area in the communication apparatus obtained from the circuit diagram of FIG. 15 is obtained.

As the method of use of the obtained frequency band, all may be used for transmission and all may be used for receiving.

Here, it is as follows when the communication apparatus obtained from FIG. 13 by FIG. 16 is summarized.

It is a communication apparatus provided with three or more band pass filter means, and the frequency band by at least two band pass filter means which center frequency characteristics adjoin among said three or more band pass filter means is distinguished and set up, without overlapping mutually.

Or the frequency of a band pass filter overlaps and it is set as a wide area.

It is a communication apparatus which can be outputted and inputted [that an output is possible or] from the input possibility of and said filter in said filter about the signal of mutually different frequency.

Also in such an embodiment, it is important to produce a more sharp skirt characteristic, using control of the above-mentioned attenuation pole, and it is also important to eliminate a noise, for example.

1. A filter characteristic regulation method which can adjust the filter property of the filter which an attenuation pole produces, and a signal can be inputted into said filter via a branch point, or a filter characteristic regulation method which adjusts the frequency region which an output of a signal is possible, adjusts the electric length of the transmission line from said branch point to said filter via said filter to said branch point, and said attenuation pole produces.

2. A filter characteristic regulator which can adjust the filter property of a filter which an attenuation pole produces, and a signal can be inputted into said filter via a branch point, or a filter characteristic regulator provided with an electric length controller which an output of a signal is possible and adjusts electric length of a transmission line from said branch point to said filter via said filter to said branch point.

3. A filter characteristic regulator which can adjust the filter property of a filter constituted by plural filter means connected via a branch point, or a filter characteristic regulator which an attenuation pole produced in at least one of said the plural filter means, and was provided with an electric length controller which adjusts electric length of a transmission line from said branch point to said each filter means.

4. A filter comprising:
a 1st band pass filter means that has 1st center frequency characteristics; and
a 2nd band pass filter means that has 2^{nd} center frequency characteristics different from said 1st center frequency characteristics, wherein
the filter is provided with an end, a transmission line of said 2nd band pass filter means which connects an end on the other hand, and a branch point formed in said transmission line of said 1st band pass filter means on the other hand, and
the filter has a frequency region which it is designed so that an attenuation pole may produce in at least one of said 1st band pass filter means or said 2nd band pass filter means, and a formation position of said branch point is adjusted, and said attenuation pole produces was adjusted.

5. The filter according to claim 4 with which at least one of said 1st band pass filter means or said 2nd band pass filter means comprised three or more steps of resonance devices, and a frequency region of an attenuation pole produced by jump coupling in said resonance device was also adjusted.

6. The filter according to claim 5 wherein the filter has a meander shape, and a frequency region of an attenuation pole produced by jump coupling in said resonance device is adjusted by adjustment of a meander radius.

7. The filter according to claim 4 distinguished and set up without a frequency band by said 1st band pass filter means and a frequency band by said 2nd band pass filter means overlapping.

8. The filter according to claim 4 which a frequency band by said 1st band pass filter means and a frequency band by said 2nd band pass filter overlapped, and was set as a wide area.

9. A filter provided with a transmission line which at least two of three or more band pass filter means which differ in center frequency characteristics mutually, and said three band pass filter means or more connect, and a branch point formed in said transmission line, or a filter with which a frequency region of said three or more band pass filter means which a formation position of said branch point is adjusted and said attenuation pole produces while being designed so that an attenuation pole may produce in either at least was adjusted.

10. The filter according to claim 9 which a frequency band by said each band pass filter means was distinguished without overlapping mutually, and was set up.

11. The filter according to claim 9 which a frequency band by at least two band pass filter means which center frequency characteristics adjoin among said three or more band pass filter means overlapped, and was set as a wide area.

12. The filter according to claim 4, wherein the filter is a co-planer filter.

13. A communication apparatus in which input possibility of or said filter to an output is possible in said filter about a signal of frequency which is provided with the filter according to claim 4, and is mutually different.

14. A communication apparatus in which other band pass filter means [some band pass filter means] which can be inputted to an output of a signal of frequency which is provided with the filter according to claim 4, and is mutually different is possible.
